(19) United States
(12) Patent Application Publication
(10) Pub. No.: US 2007/0054437 A1
(43) Pub. Date: Mar. 8, 2007

(54) OPTICAL ELEMENT AND ITS MANUFACTURING METHOD

(75) Inventors: Tsuyoshi KANEKO, Shimosuwa (JP); Yasutaka Imai, Chino (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 11/470,395

(22) Filed: Sep. 6, 2006

(30) Foreign Application Priority Data
Sep. 7, 2005 (JP) 2005-258893
Jun. 15, 2006 (JP) 2006-165760

(51) Int. Cl. H01L 21/16

(52) U.S. Cl. 438/104

(57) ABSTRACT

An optical element includes a substrate, a surface-emitting type semiconductor laser that emits laser light in a direction vertical to a surface of the substrate, and a light-receiving element formed above or below the surface-emitting type semiconductor laser provided above the substrate. The optical element includes a first insulation layer that covers a side surface and a part of an upper surface of a first columnar section that includes at least a part of the surface-emitting type semiconductor laser, and a second insulation layer that covers a side surface and a part of an upper surface of a second columnar section that includes at least a part of the light-receiving element.

The entire disclosure of Japanese Patent Application No.2005-258893, filed Sep. 7, 2006 and No.2006-165760, filed Jun. 15, 2006 are expressly incorporated by reference herein.

### BACKGROUND

1. Technical Field

The present invention relates to optical elements that emit laser light and methods for manufacturing the same.

2. Related Art

A surface-emitting type semiconductor laser is a type of optical elements that emit laser light. The surface-emitting type semiconductor laser is provided with a resonator formed in a direction vertical to a surface of the substrate, and emits laser light from the substrate surface. Compared to conventional edge-emitting type semiconductor lasers that use horizontal cleavage surfaces of a substrate as a resonator, the surface-emitting type semiconductor laser has various characteristics. For example, surface-emitting type semiconductor lasers are suitable for mass-production, capable of direct modulation, and capable of operation with low threshold values, and a two-dimensional laser array structure can be readily formed with surface-emitting type semiconductor lasers.

Also, a surface-emitting type semiconductor laser has characteristics in which its light output varies depending on ambient temperatures. For example, Japanese Laid-open Patent Application JP-A-2005-33106 and Japanese Laid-open Patent Application JP-A-2005-197514 describe optical elements in which a photo detecting element such as a photodiode is provided on a surface-emitting type semiconductor laser, a part of laser light emitted from the surface-emitting type semiconductor laser is received and monitored by the photo detecting element, and the output of the surface-emitting type semiconductor laser is controlled based on the monitored results.

The optical elements described in the aforementioned documents are equipped with a columnar section (first columnar section) in which at least a part of a surface-emitting type semiconductor laser is formed, and another columnar section (second columnar section) that is provided above the first columnar section and has a photo detecting element such as a photodiode formed therein, and have a structure in which side surfaces of the first and second columnar sections are covered by an insulation material. Also, an electrode that is connected to the light-receiving element is formed on the insulation material that covers the side surface of the second columnar section.

When the process for manufacturing optical elements includes the step of heating the optical element after the insulation layer has been formed, there is a possibility that the insulation material covering the side surfaces of the first and second columnar sections may shrink and peel off from the side surfaces of the columnar sections. When the insulation material peels off from the side surfaces of the first and second columnar sections, leakage current may be generated through leakage paths created by the side surfaces of the first and second columnar sections. Also, when the process includes the heating step to be conducted after the electrode has been formed on the insulation material, portions of the electrode may enter areas where the insulation material peels off, thereby causing leakage current, or the electrode on the insulation material may be disconnected, thereby causing the optical element to be defective, which lowers the production yield.

### SUMMARY

In accordance with an advantage of some aspects of the present invention, it is possible to provide highly efficient optical elements without electrode disconnections and with lowered leakage current, and methods for manufacturing optical elements by which the optical elements can be manufactured without lowering the yield.

An optical element in accordance with an embodiment of the present invention pertains to an optical element equipped with a substrate, a surface-emitting type semiconductor laser that emits laser light in a direction vertical to a substrate surface, and a light-receiving element formed above or below the surface-emitting type semiconductor laser provided above the substrate, wherein the optical element is equipped with a first insulation layer that covers a side surface and a part of an upper surface of a first columnar section that includes at least a part of the surface-emitting type semiconductor laser, and a second insulation layer that covers a side surface and a part of an upper surface of a second columnar section that includes at least a part of the light-receiving element.

According to the embodiment of the invention, the side surface and a part of the upper surface of the first columnar section that includes at least a part of the surface-emitting type semiconductor laser are covered by the first insulation layer, and the side surface and a part of the upper surface of the second columnar section that includes at least a part of the light-receiving element are covered by the second insulation layer. As a result, exfoliation of the first insulation layer from the first columnar section and exfoliation of the second insulation layer from the second columnar section are prevented, such that leakage current, in any, can be reduced.

In the optical element in accordance with an aspect of the embodiment of the invention, the first insulation layer may preferably cover the entire outer circumference of the upper surface of the first columnar section.

In the optical element in accordance with an aspect of the embodiment of the invention, a first electrode that joins with the upper surface of the first columnar section and electrically connects to the surface-emitting type semiconductor laser may be formed on the first insulation layer, and at least a portion of the first insulation layer below the first electrode may preferably cover the upper surface of the first columnar section.

According to the embodiment of the invention, the first insulation layer positioned below the first electrode that joins with the upper surface of the first columnar section and electrically connects to the surface-emitting type semiconductor laser covers at least the upper surface of the first columnar section, such that exfoliation of the first insulation layer from the first columnar section at least below the first electrode can be prevented, thereby eliminating disconnection of the first electrode.

In the optical element in accordance with an aspect of the embodiment of the invention, the first insulation layer may preferably cover the upper surface of the first columnar section from its outer circumferential end section toward its center by at least 1 μm.

In the optical element in accordance with an aspect of the embodiment of the invention, the second insulation layer may preferably cover the entire outer circumference of the upper surface of the second columnar section.

In the optical element in accordance with an aspect of the embodiment of the invention, a second electrode that joins with the upper surface of the second columnar section and electrically connects to the light-receiving element may be formed on the second insulation layer, and at least a portion of the second insulation layer below the second electrode may preferably cover the upper surface of the second columnar section.

According to the embodiment of the invention, the second insulation layer positioned below the second electrode that joins with the upper surface of the second columnar section and electrically connects to the light-receiving element covers at least the upper surface of the second columnar section, such that exfoliation of the second insulation layer from the second columnar section at least below the second electrode can be prevented, thereby eliminating disconnection of the second electrode.

In the optical element in accordance with an aspect of the embodiment of the invention, the second insulation layer may preferably be formed on the upper surface of the first columnar section continuously with the first insulation layer from an edge section of the first insulation layer.

According to the embodiment of the invention, the first insulation layer and the second insulation layer do not overlap each other as viewed in a plan view, such that the order of forming the first insulation layer and the second insulation layer can be appropriately changed.

In the optical element in accordance with an aspect of the embodiment of the invention, the first insulation layer may preferably cover a portion of the second insulation layer, and a second electrode that joins with the upper surface of the second columnar section and electrically connects to the light-receiving element may preferably be formed on the first insulation layer.

According to the embodiment of the invention, parasitic capacitance between the second electrode and the surface-emitting type semiconductor laser and parasitic capacitance between the second electrode and the light-receiving element can be reduced. Accordingly, high-speed operation of the surface-emitting type semiconductor laser and the optical element becomes possible.

In the optical element in accordance with an aspect of the embodiment of the invention, the second insulation layer may preferably cover the upper surface of the second columnar section from its outer circumferential end section toward its center by at least 1 μm.

A method for manufacturing an optical element in accordance with another embodiment of the invention pertains to a method for manufacturing an optical element equipped with a surface-emitting type semiconductor laser that emits laser light in a direction vertical to a substrate surface, and a light-receiving element, wherein the method includes the steps of: forming, on a substrate, a plurality of semiconductor layers for composing the surface-emitting type semiconductor laser and the light-receiving element; etching the semiconductor layers to form a first columnar section including at least a part of the surface-emitting type semiconductor laser; etching the semiconductor layers to form a second columnar section including at least a part of the light-receiving element; forming a first insulation layer that covers a side surface and a part of an upper surface of the first columnar section, and forming a second insulation layer that covers a side surface and a part of an upper surface of the second columnar section.

According to the embodiment of the invention, the first insulation layer is formed in a manner to cover the side surface and a part of the upper surface of the first columnar section that includes at least a part of the surface-emitting type semiconductor laser, and the second insulation layer is formed in a manner to cover the side surface and a part of the upper surface of the second columnar section that includes at least a part of the light-receiving element. As a result, the manufacturing method can provide highly efficient optical elements in which exfoliation of the first insulation layer from the first columnar section and exfoliation of the second insulation layer from the second columnar section are prevented, whereby leakage current can be reduced.

Further, in the method for manufacturing an optical element in accordance with an aspect of the embodiment of the invention, the step of forming the first insulation layer may preferably include the steps of forming a precursor layer that covers the side surface and the upper surface of the first columnar section, patterning the precursor layer formed on the upper surface of the first columnar section such that the precursor layer covers at least a portion of the upper surface of the first columnar section, and hardening the precursor layer.

In the method for manufacturing an optical element in accordance with an aspect of the embodiment of the invention, the precursor layer may preferably be patterned by using a dry etching method or a wet etching method.

Also, in the method for manufacturing an optical element in accordance with an aspect of the embodiment of the invention, the precursor layer may preferably be patterned such that the precursor layer covers the upper surface of the first columnar section from its outer circumferential end section toward its center by at least 1 μm.

According to the embodiment of the invention, by patterning the precursor layer such that the precursor layer covers the upper surface of the first columnar section from its outer circumferential end section toward its center by at least 1 μm, at least a portion of the upper surface of the first columnar section can be covered by the first insulation layer even when an error occurs at the time of patterning.

Also, in the method for manufacturing an optical element in accordance with an aspect of the embodiment of the invention, the step of forming the second insulation layer may preferably include the steps of forming an insulation layer that covers a side surface and an upper surface of the second columnar section, and patterning the insulation layer formed on the upper surface of the second columnar section such that the insulation layer covers a portion of the upper surface of the second columnar section.

In the method for manufacturing an optical element in accordance with an aspect of the embodiment of the invention, the insulation layer may preferably be formed by a plasma CVD method.

In the method for manufacturing an optical element in accordance with an aspect of the embodiment of the invention, the insulation layer may preferably be patterned by using a dry etching method or a wet etching method.

Furthermore, in the method for manufacturing an optical element in accordance with an aspect of the embodiment of the invention, the insulation layer may preferably be patterned such that the insulation layer covers the upper surface of the second columnar section from its outer circumferential end section toward its center by at least 1 μm.

According to the embodiment of the invention, by patterning the insulation layer such that the insulation layer covers the upper surface of the second columnar section from its outer circumferential end section toward its center by at least 1 μm, at least a portion of the upper surface of the second columnar section can be covered by the second insulation layer even when an error occurs at the time of patterning.

### BRIEF DESCRIPTION OF THE DRAWINGS

FIG. 1 is a plan view schematically showing an optical element in accordance with an embodiment of the invention.

FIG. 2 is a cross-sectional view schematically showing the optical element in accordance with the embodiment of the invention.

FIG. 3 is a cross-sectional view schematically showing the optical element in accordance with the embodiment of the invention.

FIG. 4 schematically shows a step of a method for manufacturing an optical element in accordance with an embodiment of the invention.

FIG. 5 schematically shows a step of the method for manufacturing an optical element in accordance with the embodiment of the invention.

FIG. 6 schematically shows a step of the method for manufacturing an optical element in accordance with the embodiment of the invention.

FIG. 7 schematically shows a step of the method for manufacturing an optical element in accordance with the embodiment of the invention.

FIG. 8 schematically shows a step of the method for manufacturing an optical element in accordance with the embodiment of the invention.

FIG. 9 schematically shows a step of the method for manufacturing an optical element in accordance with the embodiment of the invention.

FIG. 10 schematically shows a step of the method for manufacturing an optical element in accordance with the embodiment of the invention.

FIG. 11 schematically shows a step of the method for manufacturing an optical element in accordance with the embodiment of the invention.

FIG. 12 schematically shows a step of the method for manufacturing an optical element in accordance with the embodiment of the invention.

FIG. 13 schematically shows a step of the method for manufacturing an optical element in accordance with the embodiment of the invention.

FIG. 14 is a graph showing an example of characteristics of an optical element 10 in accordance with an embodiment of the invention.

FIG. 15 is a cross-sectional view schematically showing another optical element in accordance with another embodiment of the invention.

FIG. 16 is a cross-sectional view schematically showing another optical element in accordance with still another embodiment of the invention.

### DESCRIPTION OF EXEMPLARY EMBODIMENTS

An optical element and its manufacturing method in accordance with an embodiment of the invention are described in detail with reference to the accompanying drawings. It is noted that the embodiment to be described below indicates a part of modes of the invention, does not limit the invention, and can be appropriately modified within the scope of the invention. Also, in the drawings referred to below for describing the invention, the scale may be changed for each of the layers and each of the members such that the layers and the members can have appropriate sizes that can be recognized on the drawings.

Structure of Optical Element

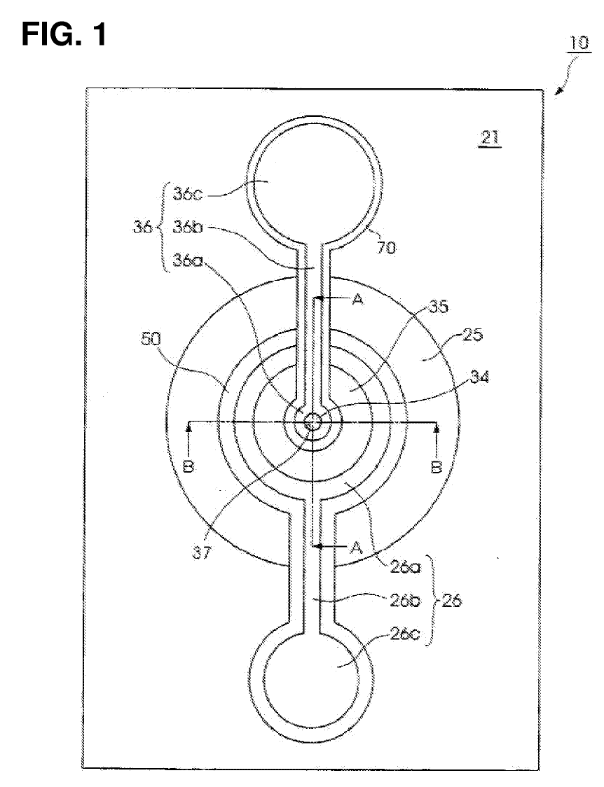

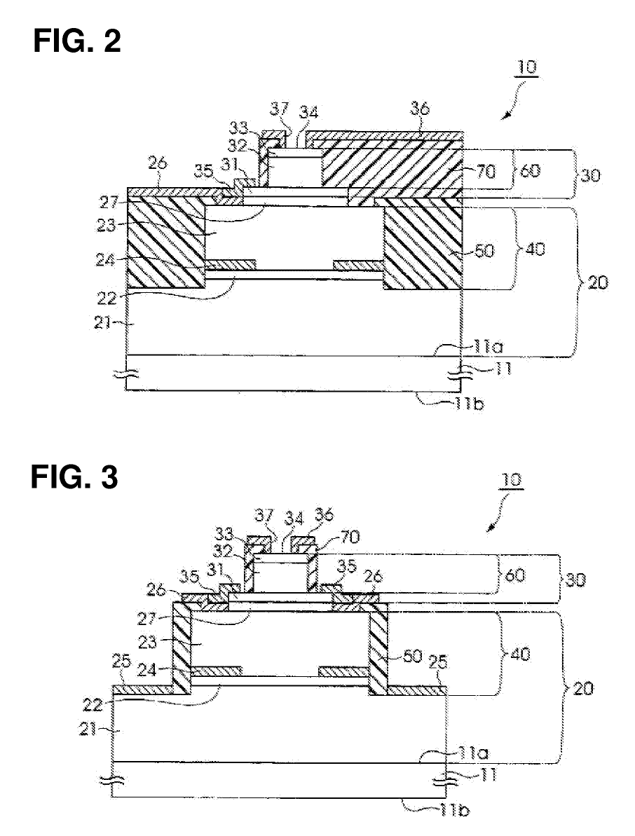

First, the structure of an optical element in accordance with an embodiment of the invention is described with reference to FIGS. 1 through 3. FIG. 1 schematically shows a plan view of the optical element in accordance with the embodiment of the invention, and FIG. 2 and FIG. 3 schematically show cross-sectional views of the optical element in accordance with the embodiment of the invention. It is noted that FIG. 2 is a cross-sectional view taken along a line A-A in FIG. 1, and FIG. 3 is a cross-sectional view taken along a line B-B in FIG. 1. As shown in FIGS. 2 and 3, the optical element 10 of the present embodiment has a structure including a surface-emitting type semiconductor laser 20 and a photodetecting element 30 as a light-receiving element. The structure of each of the elements and the entire structure of the optical element are described below.

Surface-emitting Type Semiconductor Laser

The surface-emitting type semiconductor laser 20 is formed on a semiconductor substrate 11 (e.g., an n-type GaAs substrate in the present embodiment). The surface-emitting type semiconductor laser 20 includes a vertical resonator, and in accordance with the present embodiment, one of distributed Bragg reflector mirrors and an active layer that form the vertical resonator are formed in a semiconductor deposited body (hereafter referred to as a first columnar section) 40. In other words, the surface-emitting type semiconductor laser 20 has a structure in which a part thereof is included in the first columnar section 40.

The surface-emitting type semiconductor laser 20 is formed from, for example, a distributed Bragg reflector of 40 pairs of alternately laminated n-type Al_{0.9}Ga_{0.1}As layers and n-type Al_{0.15} Ga_{0.85}As layers (hereafter called a “first mirror”) 21, an active layer 22 composed of GaAs well layers and Al_{0.3}Ga_{0.7}As barrier layers in which the well layers include a quantum well structure composed of three layers, and a distributed Bragg reflector of 25 pairs of alternately laminated p-type Al_{0.9}Ga_{0.1}As layers and p-type Al_{0.15} Ga_{0.85}As layers (hereafter called a “second mirror”) 23, which are successively stacked in layers. It is noted that the topmost layer of the second mirror 23 is composed of one of the layers with a smaller Al composition, in other words, a p-type Al_{0.15} Ga_{0.85}As layer.

In the present embodiment, the Al composition of an AlGaAs layer is a composition of aluminum (Al) with respect to gallium (Ga). The Al composition in an AlGaAs layer ranges from 0 to 1. In other words, an AlGaAs layer includes a GaAs layer (when the Al composition is 0) and an AlAs layer (when the Al composition is 1). Also, the composition of each of the layers and the number of the layers forming the first mirror 21, the active layer 22 and the second mirror 23 are not particularly limited to the above. It is noted that the Al composition of the topmost layer of the second mirror 23 may preferably be less than 0.3. The reason for this is described below.

The first mirror 21 composing the surface-emitting type semiconductor laser 20 is formed to be n-type by, for example, doping silicon (Si), and the second mirror 23 is formed to be p-type by, for example, doping carbon (C). Accordingly, the p-type second mirror 23, the active layer 22 in which no impurity is doped, and the n-type first mirror 21 form a pin diode.

A portion among the surface-emitting type semiconductor laser 20 extending from the second mirror 23 to an intermediate point of the first mirror 21 is etched in a circular shape, as viewed from an upper surface of the second mirror 23, thereby forming a first columnar section 40. It is noted that, in the present embodiment, the columnar section 40 has a plane configuration that is circular, but its configuration can have any arbitrary configuration.

Furthermore, a current constricting layer 24, that is obtained by oxidizing the AlGaAs layer from its side surface, is formed in a region near the active layer 22 among the layers composing the second mirror 23. The current constricting layer 24 is formed in a ring shape. In other words, the current constricting layer 24 has a cross section, when cut in a plane horizontal with a surface 11a of the semiconductor substrate 11 shown in FIG. 1 and FIG. 2, which is a circular ring shape concentric with a circular shape of the plane configuration of the first columnar section 40.

As shown in FIGS. 1 and 3, an electrode 25 having a plane configuration in a ring shape is provided on the first mirror 21 around the first columnar section 40. In other words, the first columnar section 40 is provided inside the electrode 25. Also, as shown in FIGS. 1 and 3, an electrode (first electrode) 26 is formed on an upper surface of the surface-emitting type semiconductor laser 20 (on the first columnar section 40). The electrode 26 has, as shown in FIG. 1, a connecting section 26a having a ring-shaped plane configuration, a lead-out section 26b having a linear plane configuration, and a pad section 26c having a circular plane configuration.

The electrode 26 is joined and electrically connected with an upper surface of the second mirror 23 at the connecting section 26a. The lead-out section 26b of the electrode 26 connects the connecting section 26a and the pad section 26c together. The pad section 26c of the electrode 26 is used as an electrode pad. The connection section 26a of the electrode 26 is provided in a manner to surround mainly an isolation layer 27 to be described below. In other words, the isolation layer 27 is provided inside the electrode 26. It is noted that, in the present embodiment, the case where the electrode 25 is provided on the first mirror 21 is described as an example, but the electrode 25 may be provided on a back surface 11b of the semiconductor substrate 11.

The electrode 25 is composed of, for example, a laminated film of an alloy of gold (Au) and germanium (Ge), and gold (Au). The electrode 26 is composed of, for example, a laminated film of platinum (Pt), titanium (Ti) and gold (Au). These electrodes 25 and 26 are used to drive the surface-emitting type semiconductor laser 20, and electric current is injected in the active layer 22 by the electrode 25 and the electrode 26. It is noted that the materials for forming the electrode 25 and the electrode 26 are not limited to those described above, and, for example, an alloy of gold (Au) and zinc (Zn) can be used.

First Insulation Layer

1-2. First Insulation layer

In the optical element 10 of the present embodiment, a first insulation layer 50 is provided on the first mirror 21 in a manner to surround mainly the circumference of the first columnar section 40. Also, the first insulation layer 50 is formed in a manner not only to cover the circumference of the first columnar section 40 but also to cover at least a portion of the upper surface of the first columnar section 40. The first insulation layer 50 is formed below the lead-out section 26b and the pad section 26c of the electrode 26. Furthermore, the first insulation layer 50 is formed below a second insulation layer 70 to be described below.

The first insulation layer 50 is formed in a manner to cover the upper surface of the first columnar section 40 in order to prevent leakage current from being generated due to exfoliation of the first insulation layer 50 from the first columnar section 40. It is noted that, if the first insulation layer 50 is peeled off from the first columnar section 40 at the time of forming the electrode 26, an electrode may be formed between the first insulation layer 50 and the first columnar section 40, which also causes leakage current. Also, as shown in FIGS. 1 and 2, because the electrode 26 is formed on a part of the upper surface of the first insulation layer 50, the first insulation layer 50 is prevented from being peeled off from the first columnar section 40, thereby preventing the electrode 26 from being disconnected.

More concretely, the first insulation layer 50 may preferably cover the upper surface of the first columnar section 40 in an area extending from its outer circumferential end section toward its center by at least 1 μm. The purpose of this structure is mainly to obtain a sufficient strength to prevent the first insulation layer 50 from peeling off the first columnar section 40. The greater the area of the first insulation layer 50 that covers the upper surface of the first columnar section 40, the better in view of preventing leakage currents that may be caused by exfoliation of the first insulation layer 50. However, to what extent the upper surface of the first columnar section 40 is to be covered may be decided in consideration of the size of the electrode 26 to be formed on the upper surface of the first columnar section 40.

Also, the first insulation layer 50 may preferably be formed along the entire outer circumference of the upper surface of the first columnar section 40 in view of preventing leakage current. However, because one of the causes that generate leakage current is exfoliation of the first insulation layer 50 from the first columnar section 40 that may occur at the time of forming the electrode 26, only a portion below the area where the electrode 26 is formed (i.e., between the upper surface of the first columnar section 40 and the electrode 26) may be covered by the first insulation layer 50. By such a structure, leakage current can be prevented, and disconnection of the electrode 26 can also be prevented.

Isolation Layer

In the optical element 10 of the present embodiment, an isolation layer 27 is formed on the surface-emitting type semiconductor laser 20. In other words, the isolation layer 27 is provided between the surface-emitting type semiconductor laser 20 and a photodetecting element 30 to be described below. Concretely, as shown in FIGS. 2 and 3, the isolation layer 27 is formed on the second mirror 23. In other words, the isolation layer 27 is provided between the second mirror 23 and a first contact layer 31 to be described below.

The isolation layer 27 has a circular plane configuration. In the illustrated example, the isolation layer 27 and the first contact layer 31 have the same plane configuration. The plane configuration of the isolation layer 27 may be made greater than the plane configuration of the first contact layer 31. The isolation layer 27 is described in greater detail in conjunction with a method for manufacturing an optical element to be described below.

Photodetecting Element

The photodetecting element 30 is provided on the isolation layer 27. The photodetecting element 30 includes a first contact layer 31, a absorption layer 32, and a second contact layer 33. The first contact layer 31 is provided on the isolation layer 27, the absorption layer 32 is provided on the first contact layer 31, and the second contact layer 33 is provided on the absorption layer 32. The plane configuration of the first contact layer 31 is made to be greater than the plane configuration of the absorption layer 32 and the second contact layer 33 (see FIG. 2 and FIG. 3). The second contact layer 33 and the absorption layer 32 compose a columnar semiconductor deposited body (hereafter referred to as a second columnar section) 60. In other words, the photodetecting element 30 has a structure having a portion thereof included in the second columnar section 60. It is noted that the upper surface of the photodetecting element 30 defines an emission surface for emitting laser light from the surface-emitting type semiconductor laser 20.

The first contact layer 31 forming the photodetecting element 30 may be composed of, for example, an n-type GaAs layer, the absorption layer 32 may be composed of, for example, a GaAs layer in which no impurity is introduced, and the second contact layer 33 may be composed of, for example, a p-type GaAs layer. More specifically, the first contact layer 31 is made to be n-type by doping, for example, silicon (Si), and the second contact layer 33 is made to be p-type by doping, for example, carbon (C). Accordingly, the n-type first contact layer 31, the absorption layer 32 without an impurity being doped, and the p-type second contact layer 33 form a pin diode.

As shown in FIG. 3, an electrode 35 that covers the first contact layer 31 is formed. A part of the electrode 35 is formed on the electrode 26. In other words, the electrode 35 and the electrode 26 are electrically connected to each other. Also, as shown in FIG. 1, the electrode 35 has a plane configuration in a ring shape. The electrode 35 is provided in a manner to surround mainly the first contact layer 31 and the second insulation layer 70. In other words, the first contact layer 31 and the second insulation layer 70 are provided inside the electrode 35.

The electrode (second electrode) 36 has, as shown in FIG. 1, a connection section 36a having a plane configuration in a ring shape, a lead-out section 36b having a plane configuration in a linear shape, and a pad section 36c having a circular plane configuration. The electrode 36 is electrically connected to the second contact layer 33 at the connection section 36a. The lead-out section 36b of the electrode 36 connects the connection section 36a and the pad section 36c together. The pad section 36c of the electrode 36 can be used as an electrode pad.

The electrode 36 is provided on the upper surface (on the second contact layer 33) of the photodetecting element 30. An aperture section 37 is provided in the electrode 36, and a part of the upper surface of the second contact layer 33 is exposed through the aperture section 37. The exposed surface is the emission surface 34 for emitting laser light. Accordingly, by appropriately setting the plane configuration and the size of the aperture section 37, the configuration and the size of the emission surface 34 can be appropriately set. In the present embodiment, as shown in FIG. 1, the emission surface 34 is in a circular shape. It is noted that, in the optical element 10 of the present embodiment, the electrode 35 and the electrode 25 may be formed with the same material, and the electrode 36 and the electrode 26 may be formed with the same material. These electrodes 35 and 36 are used for driving the photodetecting element 30.

Second Insulation Layer

In the optical element 10 in accordance with the present embodiment, a second insulation layer 70 is formed in a manner to surround mainly the second columnar section 60, and to cover at least a portion of the upper surface of the second columnar section 60. The second insulation layer 70, as shown in FIG. 1-FIG. 3, is formed over the first contact layer 31, the second mirror 23 and the first insulation layer 50. Furthermore, the second insulation layer 70 is formed below the lead-out section 36b and the pad section 36c of the electrode 36.

The second insulation layer 70 is formed in a manner to cover the upper surface of the second columnar section 60 for the same reasons as in the case of forming the first insulation layer 50 in a manner to cover the upper surface of the first columnar section 40. In other words, it is to prevent exfoliation of the second insulation layer 70 from the second columnar section 60 to thereby prevent leakage current from being generated. It is noted that, if the second insulation layer 70 is peeled off from the second columnar section 60 at the time of forming the electrode 36, an electrode may be formed between the second insulation layer 70 and the second columnar section 60, which also causes leakage current. Also, as shown in FIGS. 1 and 2, because the electrode 36 is formed on a part of the upper surface of the second insulation layer 70, the second insulation layer 70 is prevented from being peeled off from the second columnar section 60, thereby preventing the electrode 36 from being disconnected.

More concretely, the second insulation layer 70 may preferably cover the upper surface of the second columnar section 60 from its outer circumferential end section toward its center by at least 1 μm. The purpose of this structure is mainly to obtain a sufficient strength to prevent the second insulation layer 70 from peeling off the second columnar section 60. The greater the area of the second insulation layer 70 that covers the upper surface of the second columnar section 60, the better in view of preventing leakage currents that may be caused by exfoliation of the second insulation layer 70. However, to what extent the upper surface of the second columnar section 60 is to be covered may be decided in consideration of the size of the electrode 36 to be formed on the upper surface of the second columnar section 60.

Also, the second insulation layer 70 may preferably be formed along the entire outer circumference of the upper surface of the second columnar section 60 in view of preventing leakage currents. However, because one of the causes that generate leakage currents is exfoliation of the second insulation layer 70 from the second columnar section 60 that may occur at the time of forming the electrode 36, only a portion below the area where the electrode 36 is formed (i.e., between the upper surface of the second columnar section 60 and the electrode 36) may be covered by the second insulation layer 70. By such a structure, leakage current can be prevented, and disconnection of the electrode 36 can also be prevented.

Overall Structure

In the optical element 10 in accordance with the present embodiment, the n-type first mirror 21 and the p-type second mirror 23 of the surface-emitting type semiconductor laser 20, and the n-type first contact layer 31 and the p-type second contact layer 33 of the photodetecting element 30 form a npnp structure as a whole. The photodetecting element 30 is provided to monitor outputs of laser light generated by the surface-emitting type semiconductor laser 20. Concretely, the photodetecting element 30 converts laser light generated by the surface-emitting type semiconductor laser 20 into electric current. With values of the electric current, outputs of laser light generated by the surface-emitting type semiconductor laser 20 are monitored.

More specifically, in the photodetecting element 30, a part of laser light generated by the surface-emitting type semiconductor laser 20 is absorbed by the absorption layer 32, and photoexcitation is caused by the absorbed light in the absorption layer 32, and electrons and holes are generated. Then, by an electric field that is applied from an outside element, the electrons move to the electrode 35 and the holes move to the electrode 36, respectively. As a result, a current is generated in the direction from the first contact layer 31 to the second contact layer 33 in the photodetecting element 30.

Also, light output of the surface-emitting type semiconductor laser 20 is determined mainly by a bias voltage applied to the surface-emitting type semiconductor laser 20. In particular, light output of the surface-emitting type semiconductor laser 20 greatly changes depending on the ambient temperature of the surface-emitting type semiconductor laser 20 and the service life of the surface-emitting type semiconductor laser 20. For this reason, it is necessary for the surface-emitting type semiconductor laser 20 to maintain a predetermined level of light output.

In the optical element 10 in accordance with the present embodiment, light output of the surface-emitting type semiconductor laser 20 is monitored by the photodetecting element 30, and the value of a voltage to be applied to the surface-emitting type semiconductor laser 20 is adjusted based on the value of a current generated by the photodetecting element 30, whereby the value of a current flowing within the surface-emitting type semiconductor laser 20 can be adjusted. Accordingly, a predetermined level of light output can be maintained in the surface-emitting type semiconductor laser 20. The control to feed back the light output of the surface-emitting type semiconductor laser 20 to the value of a voltage to be applied to the surface-emitting type semiconductor laser 20 can be performed by using an external electronic circuit (e.g., a drive circuit not shown).

Operation of Optical Element

General operations of the optical element 10 of the present embodiment are described below. It is noted that the following method for driving the optical element 10 is described as an example, and various changes can be made within the scope of the invention. First, when a voltage in a forward direction is applied to the pin diode across the electrode 25 and the electrode 26 connected to a power supply (not shown), recombination of electrons and holes occur in the active layer 22 of the surface-emitting type semiconductor laser 20, thereby causing emission of light due to the recombination. Stimulated emission occurs during the period the generated light reciprocates between the second mirror 23 and the first mirror 21, whereby the light intensity is amplified. When the optical gain exceeds the optical loss, laser oscillation occurs, whereby laser light is emitted from the upper surface of the second mirror 23, and enters the isolation layer 27. Then, the laser light enters the first contact layer 31 of the photodetecting element 30.

Then, in the photodetecting element 30, the light entered the first contact layer 31 then enters the absorption layer 32. As a result of a part of the incident light being absorbed by the absorption layer 32, photoexcitation is caused in the absorption layer 32, and electrons and holes are generated. Then, by an electric field applied from an outside element, the electrons move to the electrode 35 and the holes move to the electrode 36, respectively. As a result, a current (photo current) is generated in the direction from the first contact layer 31 to the second contact layer 33 in the photodetecting element 30. By measuring the value of the current, light output of the surface-emitting type semiconductor laser 20 can be detected.

Method for Manufacturing Optical Element

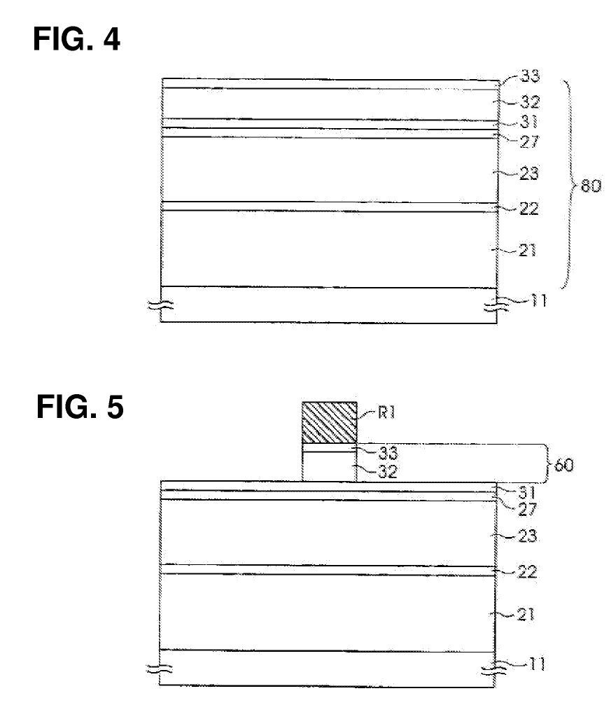

Next, one example of a method for manufacturing the optical element 10 described above is described. FIGS. 4-13 are cross-sectional views schematically showing a process of manufacturing an optical element in accordance with an embodiment of the invention. It is noted that these drawings correspond to the cross-sectional view shown in FIG. 1, respectively. To manufacture the optical element 10 of the present embodiment, first, on a surface 11a of a semiconductor substrate 11 composed of an n-type GaAs layer, a semiconductor multilayer film 80 shown in FIG. 4 is formed by epitaxial growth while modifying its composition.

It is noted here that the semiconductor multilayer film 80 is formed from, for example, a first mirror 21 of 40 pairs of alternately laminated n-type Al_{0.9}Ga_{0.1}As layers and n-type Al_{0.15} Ga_{0.85}As layers, an active layer 22 composed of GaAs well layers and Al_{0.3}Ga_{0.7}As barrier layers in which the well layers include a quantum well structure composed of three layers, a second mirror 23 of 25 pairs of alternately laminated p-type Al_{0.9}Ga_{0.1}As layers and p-type Al_{0.15} Ga_{0.85}As layers, an isolation layer 27 composed of an AlGaAs layer without impurities being doped, a first contact layer 31 composed of an n-type GaAs layer, a absorption layer 32 composed of a GaAs layer without impurities being doped, and a second contact layer 33 composed of a p-type GaAs layer. These layers are sequentially laminated on the semiconductor substrate 11, thereby forming the semiconductor multilayer film 80. It is noted that the isolation layer 27 can be composed of a p-type or n-type AlGaAs layer.

The isolation layer 27 whose etching rate to a second etchant to be described below is greater than an etching rate of an uppermost layer of the second mirror 23 to the second etchant may preferably be used. More concretely, for example, the isolation layer 27 may preferably be composed of an AlGaAs layer having an Al composition that is greater than an Al composition of the uppermost layer of the second mirror 23. In other words, when the second mirror 23 is grown, the uppermost layer of the second mirror 23 is formed to become an AlGaAs layer having an Al composition smaller than the Al composition of the isolation layer 27. More specifically, the uppermost layer of the second mirror 23 and the isolation layer 27 may preferably be formed such that the Al composition of the uppermost layer of the second mirror 23 is less than 0.3, and the Al composition of the isolation layer 27 is more than 0.3.

The isolation layer 27 whose etching rate to a first etchant to be described below is smaller than an etching rate of the first contact layer 31 to the first etchant may preferably be used. More concretely, for example, the isolation layer 27 can be composed of an AlGaAs layer having an Al composition that is greater than an Al composition of the first contact layer 31. In other words, when the first contact layer 31 is grown, the first contact layer 31 is formed to become an AlGaAs layer (including a GaAs layer) having an Al composition smaller than the Al composition of the isolation layer. More specifically, the first contact layer 31 and the isolation layer 27 may preferably be formed such that the Al composition of the first contact layer 31 is less than 0.3, and the Al composition of the isolation layer 27 is more than 0.3.

It is noted that, when the second mirror 23 is grown, at least one layer thereof near the active layer 22 is formed to be a layer that is later oxidized and becomes a current constricting layer 24 (see FIG. 9). More concretely, the layer that becomes to be the current constricting layer 24 is formed to be an AlGaAs layer (including an AlAs layer) having an Al composition that is greater than an Al composition of the isolation layer 27. In other words, the isolation layer 27 can be formed to be an AlGaAs layer whose Al composition is smaller than that of the layer that becomes to be the current constricting layer 24. By this, in an oxidizing process (see FIG. 9) for forming the current constricting layer 24 to be described below, the isolation layer 27 is not oxidized. More specifically, the layer that becomes to be the current constricting layer 24 and the isolation layer 27 may preferably be formed such that the Al composition of the layer that becomes to be the current constricting layer 24 is more than 0.95, and the Al composition of the isolation layer 27 is less than 0.95. An optical film thickness of the isolation layer 27 may preferably be, for example, an odd multiple of λ/4, when a design wavelength of the surface-emitting type semiconductor laser 20 (see FIG. 2 and FIG. 3) is λ.

Also, the sum of optical film thickness of the first contact layer 31, the absorption layer 32 and the second contact layer 33, in other words, the optical film thickness of the entire photodetecting element 30 (see FIG. 2 and FIG. 3), may preferably be, for example, an odd multiple of λ/4. As a result, the entire photodetecting element 30 can function as a distributed reflection type mirror. In other words, the entire photodetecting element 30 can function as a distributed reflection type mirror above the active layer 22 in the surface-emitting type semiconductor laser 20. Accordingly, the photodetecting element 30 can function as a distributed reflection type mirror without adversely affecting the characteristics of the surface-emitting type semiconductor laser 20.

Also, when a second electrode 26 is formed in a later step, at least a portion of the second mirror 23 near an area contacting the electrode 26 may preferably be formed with a high carrier density such that ohmic contact can be readily made with the electrode 26. Similarly, at least a portion of the first contact layer 31 near an area contacting the electrode 35 may preferably be formed with a high carrier density such that ohmic contact can be readily made with the electrode 35.

The temperature at which the epitaxial growth is conducted is appropriately decided depending on the growth method, the kind of raw material, the type of the semiconductor substrate 11, and the kind, thickness and carrier density of the semiconductor multilayer film 80 to be formed, and may preferably be set generally at 450° C.-800° C. Also, the time required for conducting the epitaxial growth is appropriately decided like the temperature. Also, a metal-organic vapor phase deposition (MOVPE: Metal-Organic Vapor Phase Epitaxy) method, a MBE method (Molecular Beam Epitaxy) method or a LPE (Liquid Phase Epitaxy) method can be used as a method for the epitaxial growth.

Next, as shown in FIG. 5, a second columnar section 60 is formed. To form the second columnar section 60, first, resist (not shown) is coated on the semiconductor multilayer film 80, and then the resist is patterned by a lithography method. As a result, a resist layer R1 having a specified plane configuration is formed on the upper surface of the second contact layer 33. Then, by using the resist layer R1 as a mask, the second contact layer 33 and the absorption layer 32 are etched by, for example, a dry etching method. By this, the second contact layer 33 and the absorption layer 32 having the same plane configuration as that of the second contact layer 33 are formed. As a result, the second columnar section 60 is formed. When the second columnar section 60 is formed, the resist layer R1 is removed.

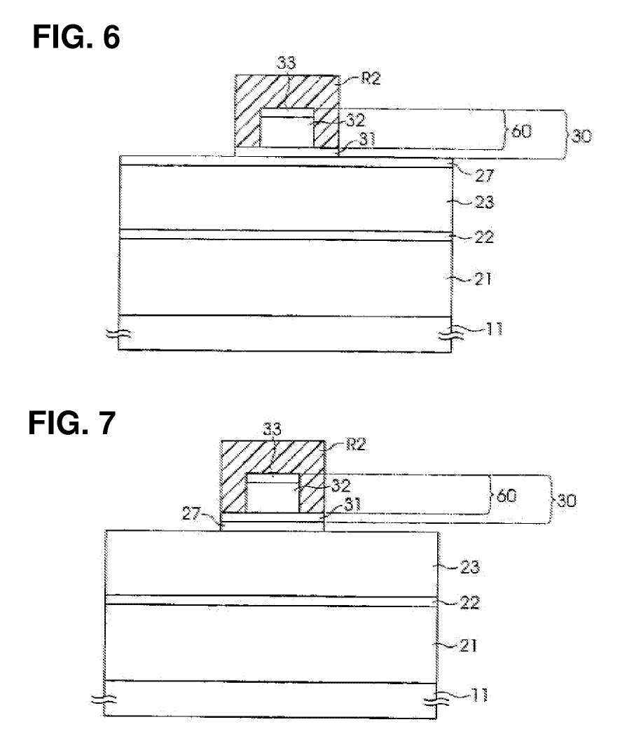

When the second columnar section 60 is formed, the first contact layer 31 is patterned into a specified configuration, as shown in FIG. 6. More concretely, first, resist (not shown) is coated on the first contact layer 31, and then the resist is patterned by a lithography method. As a result, a resist layer R2 having a specified pattern that covers the second columnar section 60 is formed on the first contact layer 31. Next, by using the resist layer R2 as a mask, the first contact layer 31 is etched with a first etchant. At this time, because the isolation layer 27 is disposed below the first contact layer 31, and the isolation layer 27 functions as an etching stopper layer, etching of the first contact layer 31 can be accurately and readily stopped at the time when the isolation layer 27 is exposed. More concretely, the following is conducted.

As described above, the isolation layer 27 having an etching rate to the first etchant that is smaller than an etching rate of the first contact layer 31 to the first etchant can be used. By using the first etchant, the first contact layer 31 is etched at a greater etching rate until the isolation layer 27 is exposed. The etching rate of the isolation layer 27 is smaller than the etching rate of the first contact layer 31. In other words, the isolation layer 27 is more difficult to be etched compared to the first contact layer 31. Accordingly, at the time when the isolation layer 27 is exposed, etching with the first etchant becomes difficult to take place, and therefore it is easy to stop etching at this point of time. In other words, etching of the first contact layer 31 can be accurately and readily stopped at the time when the isolation layer 27 is exposed.

More concretely, for example, the isolation layer 27 can be composed of an AlGaAs layer having an Al composition greater than the Al composition of the first contact layer 31. Then, the first etchant can be selected such that the etching rate of the AlGaAs layer having a large Al composition is smaller, and the etching rate of the AlGaAs layer having a small Al composition is larger. In other words, the first etchant that selectively etches the AlGaAs layer having a small Al composition can be selected. By this, the etching rate of the isolation layer 27 to the first etchant can be made smaller than the etching rate of the first contact layer 31 to the first etchant.

As described above, the Al composition of the isolation layer 27 is preferably more than 0.3, and the Al composition of the first contact layer 31 is preferably less than 0.3. When the isolation layer 27 is formed in such a range, a mixed solution of ammonia, hydrogen peroxide and water can be used as the first etchant. For example, the mixing ratio of ammonia, hydrogen peroxide and water that is about 1:10:150 can be used, but this mixing ratio is not particularly limited, and can be appropriately decided.

As a result, as shown in FIG. 6, the photodetecting element 30 is formed. The photodetecting element 30 includes the second contact layer 33, the absorption layer 32 and the first contact layer 31. Also, the plane configuration of the first contact layer 31 may be formed to be greater than the plane configuration of the second contact layer 33 and the absorption layer 32. In the process described above, after the second contact layer 33 and the absorption layer 32 are patterned, the first contact layer 31 is patterned. However, after the first contact layer 31 may be patterned, the second contact layer 33 and the absorption layer 32 may be patterned.

When the photodetecting element 30 is formed, the isolation layer 27 is patterned into a specified configuration, as shown in FIG. 7. More concretely, by using the resist layer R2 described above as a mask, the isolation layer 27 is etched with a second etchant. At this time, because the uppermost layer of the second mirror 23 is disposed below the isolation layer 27, and the uppermost layer of the second mirror 23 functions as an etching stopper layer, etching of the isolation layer 27 can be accurately and readily stopped at the time when the uppermost layer of the second mirror 23 is exposed. More concretely, the following is conducted.

As described above, the isolation layer 27 having an etching rate to the second etchant that is greater than an etching rate of the uppermost layer of the second mirror 23 to the second etchant can be used. By using the second etchant, the isolation layer 27 is etched at a greater etching rate until the uppermost layer of the second mirror 23 is exposed. The etching rate of the uppermost layer of the second mirror 23 is smaller than the etching rate of the isolation layer 27. In other words, the uppermost layer of the second mirror 23 is more difficult to be etched compared to the isolation layer 27. Accordingly, at the time when the uppermost layer of the second mirror 23 is exposed, etching with the second etchant becomes difficult to take place, and therefore it is easy to stop etching at this point of time. In other words, etching of the isolation layer 27 can be accurately and readily stopped at the time when the uppermost layer of the second mirror 23 is exposed.

More concretely, for example, the isolation layer 27 can be composed of an AlGaAs layer having an Al composition greater than the Al composition of the uppermost layer of the second mirror 23. Then, the second etchant can be selected such that the etching rate of the AlGaAs layer having a large Al composition is greater, and the etching rate of the AlGaAs layer having a small Al composition is smaller. In other words, the second etchant that selectively etches the AlGaAs layer having a large Al composition can be selected. By this, the etching rate of the isolation layer 27 to the second etchant can be made greater than the etching rate of the uppermost layer of the second mirror 23 to the second etchant.

As described above, the Al composition of the isolation layer 27 is preferably more than 0.3, and the Al composition of the uppermost layer of the second mirror 23 is preferably less than 0.3. When the isolation layer 27 is formed in such a range, for example, hydrofluoric acid can be used as the second etchant. The concentration of the hydrofluoric acid may be about 0.1%, for example, but the concentration of the hydrofluoric acid can be appropriately decided without any particular limitation.

As a result, as shown in FIG. 7, the isolation layer 27 that is patterned is formed. Then, the resist layer R2 is removed. In the illustrated example, the plane configuration of the isolation layer 27 is made to be the same as the plane configuration of the first contact layer 31. But the plane configuration of the isolation layer 27 can be made to be greater than the plane configuration of the first contact layer 31. More concretely, instead of the resist layer R2 that is used for patterning the isolation layer 27 described above, another resist layer having a plane configuration greater than that of the resist layer R2 may be used to pattern the isolation layer 27.

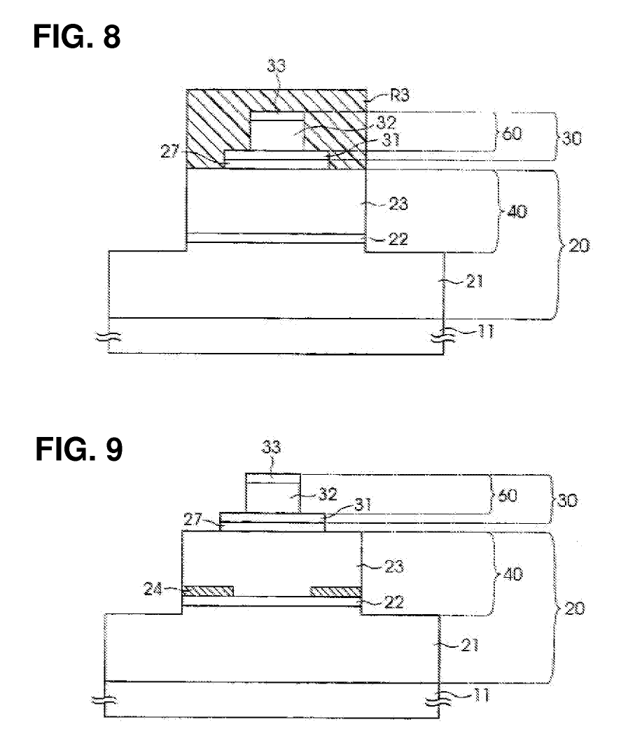

Next, a surface-emitting type semiconductor laser 20 including a first columnar section 40 is formed, as shown in FIG. 8. Concretely, first, resist (not shown) is coated on the second mirror 23, and then the resist is patterned by a lithography method, thereby forming a resist layer R3 having a specified pattern. Then, by using the resist layer R3 as a mask, the second mirror 23, the active layer 22 and a part of the first mirror 21 are etched by, for example, a dry etching method. By this, the first columnar section 40 is formed, as shown in FIG. 8.

By the process described above, a vertical resonator including the first columnar section 40 (surface-emitting type semiconductor laser 20) is formed on the semiconductor substrate 11. In other words, a laminated body of the surface-emitting type semiconductor laser 20, the isolation layer 27 and the photodetecting element 30 is formed. Then, the resist layer R3 is removed. In the present embodiment, as described above, the photodetecting element 30 and the isolation layer 27 are first formed, and then the first columnar section 40 is formed. However, the first columnar section 40 may be formed first, and then the photodetecting element 30 and the isolation layer 27 may be formed.

Next, a current constricting layer 24 is formed, as shown in FIG. 9. To form the current constricting layer 24, the semiconductor substrate 11 on which the first columnar section 40 is formed through the aforementioned steps is placed in a water vapor atmosphere at, for example, about 400° C. As a result, a layer having a high Al composition provided in the second mirror 23 described above is oxidized from its side surface, whereby the current constricting layer 24 is formed. As described above, in this step, it is possible that the isolation layer 27 is not oxidized.

The oxidation rate depends on the temperature of the furnace, the amount of water vapor supply, and the Al composition and the film thickness of the layer to be oxidized. In a surface-emitting type laser equipped with the current constricting layer 24 that is formed by oxidation, current flows only in a portion where the current constricting layer 24 is not formed (a portion that is not oxidized). Accordingly, in the process of forming the current constricting layer 24, the range of the current constricting layer 24 to be formed may be controlled, whereby the current density can be controlled. Also, the diameter of the current constricting layer 24 may preferably be adjusted such that a major portion of laser light that is emitted from the surface-emitting type semiconductor laser 20 enters the first contact layer 31.

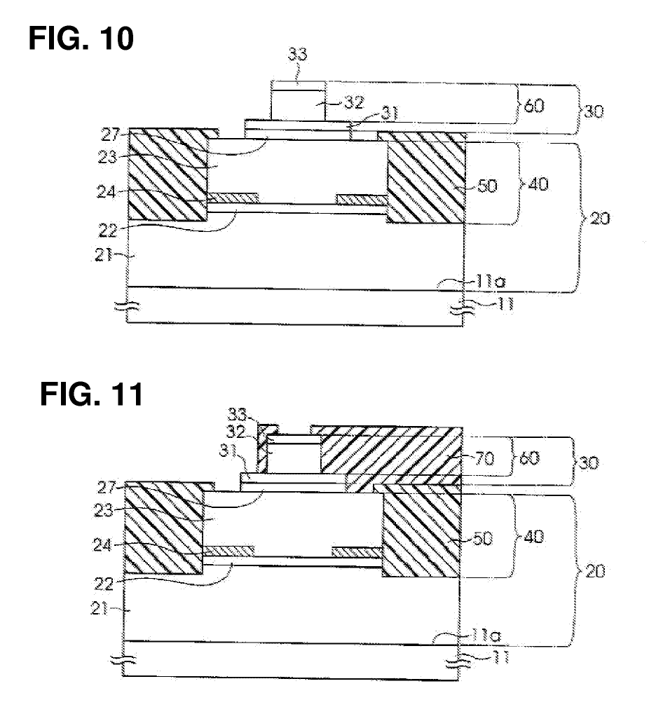

Next, as shown in FIG. 10, a first insulation layer 50 is formed on the first mirror 21, around the first columnar section 40 and on at least a portion of the upper surface of the first columnar section 40 (for example, on an upper surface outer circumference of the first columnar section 40). The first insulation layer 50 may preferably be composed of a material that is easier to make a thick film compared to a second insulation layer 70 to be described below. The film thickness of the first insulation layer 50 may be, for example, about 2-4 μm, but it is not particularly limited, and may be thicker than the film thickness of the second insulation layer 70.

For example, the first insulation layer 50 can be formed from material that is obtained by hardening liquid material settable by energy, such as, heat, light or the like (for example, a precursor of ultraviolet setting type resin or thermosetting type resin). As the ultraviolet setting type resin, for example, an acrylic resin, an epoxy resin or the like that is an ultraviolet setting type can be enumerated. Also, as the thermosetting type resin, a polyimide resin or the like that is a thermosetting type can be enumerated. Furthermore, for example, the first insulation layer 50 may be composed of a laminated layered film using a plurality of the materials described above.

In this exemplary embodiment, the case where a precursor of polyimide resin is used as the material for forming the first insulation layer 50 is described. First, for example, by using a spin coat method, the precursor (precursor of polyimide resin) is coated on the semiconductor substrate 11, thereby forming a precursor layer. In this instance, the precursor layer is formed in a manner to cover the upper surface of the first columnar section 40. It is noted that, as the method for forming the precursor layer, besides the aforementioned spin coat method, another known technique, such as, a dipping method, a spray coat method, an ink jet method or the like can be used.

Then, the semiconductor substrate 11 is heated by using, for example, a hot plate or the like, thereby removing the solvent, and then is placed in a furnace at about 350° C. to thereby imidize the precursor layer, whereby a polyimide resin layer that is almost completely set is formed. Then, as shown in FIG. 10, the polyimide resin layer is patterned by using a known lithography technique, thereby forming the first insulation layer 50. In this instance, the first insulation layer 50 may preferably be formed to cover the upper surface of the first columnar section 40 in an area extending from its outer circumferential edge section toward its center by at least 1 μm.

It is noted that, as shown in FIG. 1, the first insulation layer 50 is patterned to have an external configuration in a circular shape. To provide such a shape, portions of the precursor layer formed on the second mirror 23 other than the portion thereof that becomes to be the first insulation layer 50 need to be removed. The thickness of the precursor layer formed on the second mirror 23 is entirely different from the thickness of the precursor layer that is formed and covers the upper surface of the first columnar section 40, and therefore the patterning of the precursor layer may preferably be conducted in two divided steps. For example, in the first patterning, portions other than the portion that becomes to be the first insulation layer 50 may be patterned such that the outer configuration of the first insulation layer 50 becomes to be circular, and in the second patterning, the precursor layer covering the upper surface of the first columnar section 40 may be removed such that the first insulation layer 50 covers the upper surface of the first columnar section 40 in an area extending from its outer circumferential edge section toward its center by at least 1 μm.

As the etching method used for patterning, a dry etching method or the like can be used. Dry etching can be conducted with, for example, oxygen or argon plasma. In the method for forming the first insulation layer 50 described above, an example in which a precursor layer of polyimide resin is hardened and then patterning is conducted is described. However, before hardening the precursor layer of polyimide resin, patterning may be conducted. As the etching method used for this patterning, a wet etching method or the like may be used. The wet etching may be conducted with, for example, an alkaline solution or an organic solution.

Next, as shown in FIG. 11, a second insulation layer 70 is formed on the first contact layer 31, around the second columnar section 60 and on at least a portion of the upper surface of the second columnar section 60 (for example, on an upper surface outer circumference of the second columnar section 60). The second insulation layer 70 can use material that is easy to perform fine processing compared with the first insulation layer 50. The film thickness of the second insulation layer 70 may be, for example, about 0.1-0.5 μm, but it is not particularly limited, and may be thinner than the film thickness of the first insulation layer 50. For example, as the second insulation layer 70, an inorganic dielectric film such as a silicon oxide film, a silicon nitride film, or the like, or a laminated layered film of the foregoing materials can be used. Concretely, the method for forming the second insulation layer 70 is conducted as follows.

First, an insulation layer (not shown) is formed over the entire surface of the semiconductor substrate 11 on which the surface-emitting type semiconductor laser 20 and the photodetecting element 30 are formed. This insulation layer can be formed by, for example, a plasma CVD. Next, by using a known lithography technique, the insulation layer is patterned, thereby forming a second insulation layer 70. The second insulation layer 70 can be patterned more finely compared to the first insulation layer 50, as described above. In this instance, the second insulation layer 70 may preferably be formed to cover the upper surface of the second columnar section 60 in an area extending from its outer circumference edge section toward its center by at least 1 μm.

It is noted that, as shown in FIG. 1, the second insulation layer 70 is patterned to have a plane configuration according to the shape of an electrode 36. To provide such a shape, portions of the insulation layer formed to cover the first insulation layer 50, the first columnar section 40 and the photodetecting element 30 other than the portion thereof that becomes to be the second insulation layer 70 need to be removed. The thickness of the insulation layer formed on the first insulation layer 50 and the first columnar section 40 is entirely different from the thickness of the insulation layer that is formed on the photodetecting element 30 (on the upper surface of the second columnar section 60), and therefore the patterning of the insulation layer may preferably be conducted in two divided steps. For example, in the first patterning, portions other than the portion that becomes to be the second insulation layer 70 may be patterned such that the configuration of the second insulation layer 70 becomes to be in a shape according to the configuration of the electrode 36, and in the second patterning, the insulation layer covering the upper surface of the second columnar section 60 may be removed such that the second insulation layer 70 covers the upper surface of the second columnar section 60 in an area extending from its outer circumferential edge section toward its center by at least 1 μm.

As the etching method used for this patterning, a dry etching method or a wet etching method can be used. The dry etching can be conducted with plasma containing fluorine radical, for example. The wet etching can be conducted with hydrofluoric acid, for example.

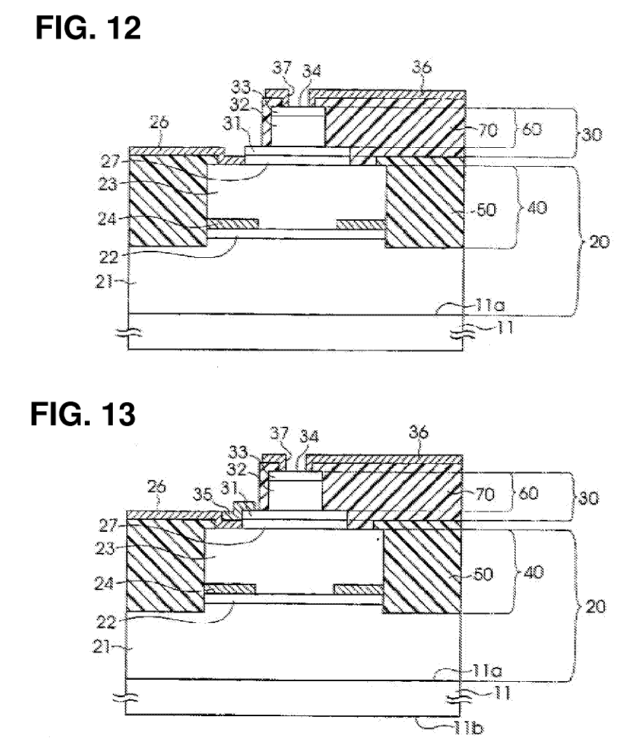

When the steps described above are completed, an electrode 26 is formed on the upper surface of the second mirror 23, and an electrode 36 is formed on the upper surface of the photodetecting element 30 (an upper surface of the second contact layer 33), as shown in FIG. 12. As shown in FIGS. 1-3, the electrode 26 has a connecting section 26a having a ring-shaped plane configuration, a lead-out section 26b having a linear plane configuration, and a pad section 26c having a circular plane configuration, and it is noted that the connecting section 26a is formed on the upper surface of the second mirror 23, and the lead-out section 26b and the pad section 26c are formed on the first insulation layer 50. Further, the electrode 36 has a connection section 36a having a plane configuration in a ring shape, a lead-out section 36b having a plane configuration in a linear shape, and a pad section 36c having a circular plane configuration, and it is noted that the connecting section 36a is formed on the upper surface of the second contact layer 33, and the lead-out section 36b and the pad section 36c are formed on the second insulation layer 70.

In accordance with an exemplary method, the electrodes 26 and 36 may be formed as follows. First, before the electrode 26 and the electrode 36 are formed, the upper surface of the second mirror 23 and the upper surface of the second contact layer 33 are washed by a plasma processing method or the like, if necessary. As a result, an element with more stable characteristics can be formed. Next, a laminated film (not shown) of platinum (Pt), titanium (Ti), and gold (Au), for example, is formed by, for example, a vacuum deposition method. Then, the electrode 26 and the electrode 36 are formed by removing the laminated film other than specified positions by a lift-off method.

In this instance, a portion where the above-mentioned laminated film is not formed is formed on the upper surface of the second contact layer 33. This portion becomes an aperture section 37, and a portion of the upper surface of the second contact layer 33 is exposed through the aperture section 37. The exposed surface becomes an emission surface 34 of laser light. As described above, the electrode 26 can include at least platinum (Pt). The electrode 26 can use an alloy of gold (Au) and zinc (Zn), for example. Preferably, the electrode 26 includes platinum. The reason is as follows.

It the optical element 10 in accordance with the present embodiment, the electrode 26 contacts the p-type second mirror 23 (see FIG. 3 and FIG. 3). If the electrode 26 includes zinc (Zn), it is possible that zinc may diffuse in the p-type second mirror 23 in an anneal processing step to be described below, since zinc thermally diffuses in an amount greater than that of platinum, and may reach the adjacent n-type first contact layer 31. Because zinc is a p-type dopant in the first contact layer 31 that is composed of a GaAs layer, it may change the n-type first contact layer 31 to p-type. As a result, the pin structure in the photodetecting element 30 may be destroyed. In contrast, platinum has a smaller thermal diffusion amount compared to zinc, and therefore the n-type first contact layer 31 can be prevented from being changed to p-type.

It is noted that a dry etching method or a wet etching method can be used in the above-described process instead of the lift-off method. Also, in the process described above, a sputtering method can be used instead of the vapor deposition method. Further, in the process described above, although the electrode 26 and the electrode 36 are patterned at the same time, the electrode 26 and the electrode 36 can be formed individually.

Next, by a similar method used in forming the electrodes 26 and 36, a laminated film of an alloy of gold (Au) and germanium (Ge), and gold (Au) is patterned, whereby an electrode 35 is formed on the first contact layer 31 of the photodetecting element 30 as shown in FIG. 13. In this process, an electrode 25 may be formed on the first mirror 21 of the surface-emitting type semiconductor laser 20 together with the electrode 35 (see FIG. 1 and FIG. 2). The electrode 25 and the electrode 35 may be formed by patterning them at the same time, or the electrode 25 and the electrode 35 may be formed by patterning them individually.

Finally, an annealing treatment is conducted. The temperature of the annealing treatment depends on the electrode material. This is usually conducted at about 400° C. for the electrode material used in the present embodiment. The electrodes 25, 26, 35 and 36 are formed with the process described above. By the process described above, the optical element 10 shown in FIGS. 1-3 in accordance with the present embodiment is manufactured.

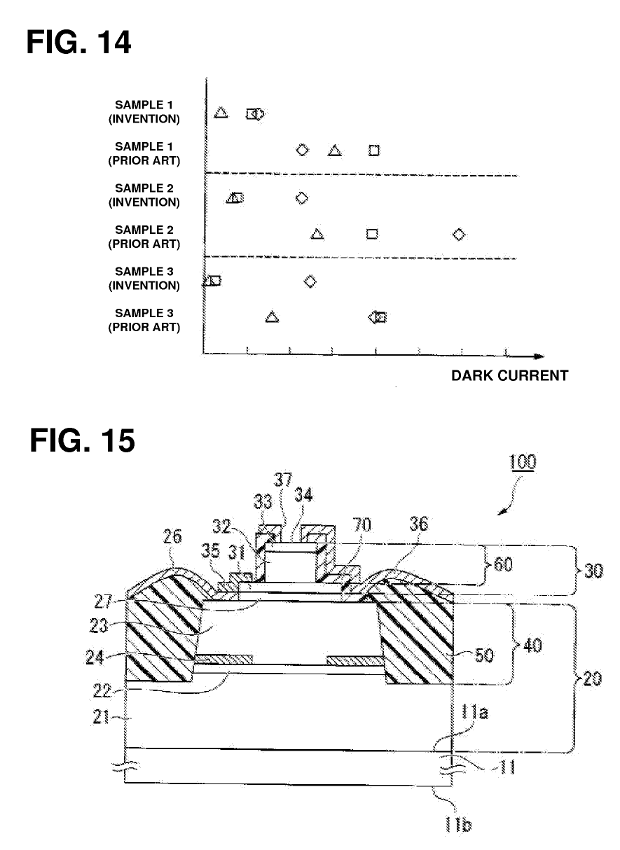

Optical elements 10 having the structure described above were manufactured by the manufacturing method described above, and characteristics of the optical elements 10 were measured. FIG. 14 is a graph showing, as an example, the characteristics of the optical elements 10 in accordance with embodiments of the invention. FIG. 14 shows the results of measurement of dark current generated in the photodetecting element 30 of the optical element 10. It is noted that, for comparison, FIG. 14 also shows the results of measurement of dark current generated in photodetecting elements provided in optical elements having a conventional structure in which the second insulation layer 70 does not cover the upper surface of the second columnar section 60.

FIG. 14 shows the results obtained from three kinds of samples, i.e., First-Third Samples, in which diameters of the second columnar sections 60 are different from one another. Concretely, the diameter of the second columnar section 60 of First Sample is 17 μm, the diameter of the second columnar section 60 of Second Sample is 19 μm, and the diameter of the second columnar section 60 of Third Sample is 21 μm. Plural sample pieces were manufactured for each of First-Third Samples, and FIG. 14 shows three representative results of measurement for each of First-Third Samples. It is understood from FIG. 14 that all First-Third Samples show the tendency in which the dark current in the samples manufactured according to the invention is reduced compared to those of the conventional structure.

Furthermore, optical elements 10 were manufactured by the manufacturing method of the invention, and disconnection of the electrode 26 formed on the first columnar section 40 in each of the manufactured optical elements 10 was measured. Concretely, 144 pieces of the optical elements were measured. In optical elements having the conventional structure, many electrodes that correspond to the electrode 26 were disconnected, where the number of non-defective elements was 17, and the non-defective rate was 11.8%. In contrast, among the optical elements 10 manufactured by the manufacturing method of the invention, the number of non-defective elements was 144, which was an improvement to the non-defective rate of 100%. In view of the above, it is understood that the optical element 10 in accordance with the invention can be manufactured with high yield, and is a high performance optical element that generates few dark current.

As described above, in the optical element 10 in accordance with the embodiment of the invention, the first insulation layer 50 is formed around the first columnar section 40 and on at least a part of the upper surface of the first columnar section 40, and the second insulation layer 70 is formed around the second columnar section 60 and on at least a part of the upper surface of the second columnar section 60. As a result, exfoliation of the first insulation layer 50 from the first columnar section 40 and exfoliation of the second insulation layer 70 from the second columnar section 60 are prevented, whereby leakage current can be reduced.

An embodiment of the invention is described above. However, the invention is not limited to the embodiment described above, and can be freely modified within the scope of the invention. For example, in accordance with another embodiment of the invention, an optical element 100 having a structure shown in FIG. 15 can be provided. In the optical element 100, a first insulation layer 50 is formed to cover the side surface and a part of the upper surface of a first columnar section 40, and a second insulation layer 70 is formed continuously from an edge section of the first insulation layer 50 as viewed in a plan view.

In other words, the edge section of the first insulation layer 50 on the side of the first columnar section 40 coincides with the edge section of the second insulation layer 70 on the side of the first columnar section 40. Further, an electrode 36 is formed on the first insulation layer 50 and the second insulation layer 70.

It is noted here that, because the first insulation layer 50 is formed by hardening a settable liquid material, the first insulation layer 50 has a raised portion formed near the edge section of the first columnar section 40. Also, the side wall of the first columnar section 40 and the surface 11a of the semiconductor substrate 11 define an angle that is less than 90 degrees, such that the outer diameter of the first columnar section 40 gradually reduces from its bottom surface section toward its upper surface section.

The optical element 100 can be manufactured by a process similar to the embodiment described above. However, as the first insulation layer 50 and the second insulation layer 70 do not overlap each other as viewed in a plan view, the sequence in the step for forming the first insulation layer 50 and the step for forming the second insulation layer 70 can be changed. The optical element 100 having such a structure has actions and effects similar to those of the above-described embodiment.

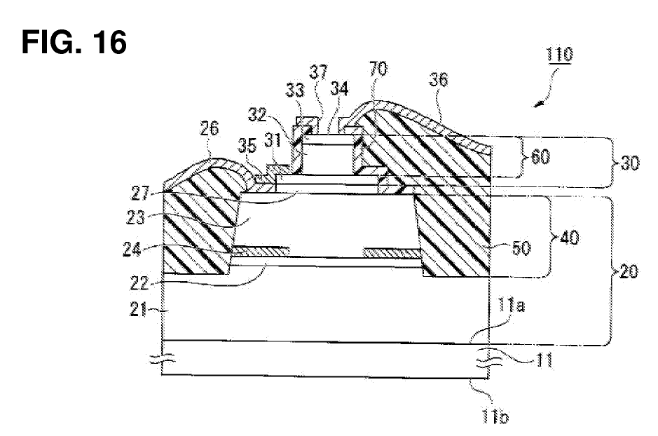

Also, in accordance with still another embodiment of the invention, an optical element 110 having a structure shown in FIG. 16 may be provided. In the optical element 110, a first insulation layer 50 is formed to cover a portion of a second insulation layer 70. Furthermore, an electrode 36 is formed on the first insulation layer 50 and on the upper surface of the second insulation layer 70 at an edge section thereon on the side of an emission surface 34.

It is noted here that, because the first insulation layer 50 is formed by hardening a settable liquid material, the first insulation layer 50 has a raised portion formed near the edge section of the second columnar section 60. Also, the side wall of the first columnar section 40 and the surface 11a of the semiconductor substrate 11 define an angle that is less than 90 degrees, such that the outer diameter of the first columnar section 40 gradually reduces from its bottom surface section toward its upper surface section.

The optical element 110 having such a structure has actions and effects similar to those of the above-described embodiments. However, because the thick first insulation layer 50 is formed on the second insulation layer 70, the distance between the electrode 36 and the photodetecting element 30 and the distance between the electrode 36 and the surface-emitting type semiconductor laser 20 become greater, such that parasitic capacitances between the electrode 36 and the surface-emitting type semiconductor laser 20 and between the electrode 36 and the photodetecting element 30 can be reduced. Therefore, high-speed operations of the surface-emitting type semiconductor laser 20 and the photodetecting element 30 become possible.

Furthermore, the embodiments are described above, using examples in which the photodetecting element 30 is provided above the surface-emitting type semiconductor laser 20 through the isolation layer 27. However, the invention is also applicable to optical elements having a structure described in, for example, Japanese Examined Patent Application Publication JP-B-7-56552 and Japanese Laid-open Patent Application JP-A-6-37299, in which a surface-emitting type semiconductor laser is provided above a photodetecting element.

Also, in the embodiments described above, the photodetecting element 30 is provided to detect the light intensity of laser light emitted from the surface-emitting type semiconductor laser 20. However, the photodetecting element 30 can also be used to detect external light. More specifically, for example, the optical element may be used for optical communications, wherein laser light emitted from the surface-emitting type semiconductor laser 20 may be used for optical signals to be transmitted, and optical signals transmitted can be detected by the photodetecting element 30. Light signals received by the photodetecting element 30 are retrieved as electrical signals through the electrodes 35 and 36.

Moreover, for example, interchanging the p-type and n-type characteristics of each of the semiconductor layers in the above described embodiments does not deviate from the subject matter of the present invention. In this case, the p-type first mirror 21 and the n-type second mirror 23 of the surface-emitting type semiconductor laser 20, and the p-type first contact layer 31 and the n-type second contact layer 33 of the photodetecting element 30 can form a pnpn structure as a whole. In this case, the materials of the electrode 26 and the electrode 35 described above can be interchanged. In other word, the electrode 26 that contacts the n-type second mirror 23 can use a laminated film of an alloy of gold (Au) and germanium (Ge) and gold (Au), and the electrode 35 that contacts the p-type first contact layer 31 can use a material including platinum (Pt).

Furthermore, for example, in one of the surface-emitting type semiconductor laser 20 and the photodetecting element 30, the p-type and n-type characteristics in each of the layers may be interchanged, whereby the surface-emitting type semiconductor laser 20 and the photodetecting element 30 can form an npn structure or a pnp structure as a whole. In such a structure, the second columnar section 60 can include the first contact layer 31. Also, in the embodiments described above, examples in which the isolation layer 27 is formed between the second mirror 23 and the first contact layer 31 are described. However, a structure in which the isolation layer 27 between the second mirror 23 and the first contact layer 31 is omitted can also be provided in accordance with an embodiment of the invention.

What is claimed is:

1. An optical element comprising:
a surface-emitting type semiconductor having a first columnar section;
a light-receiving element having a second columnar section, the light-receiving element is formed above the first columnar section;
a first insulation layer that covers a side surface and a part of an upper surface of the first columnar section; and
a second insulation layer that covers a side surface and a part of an upper surface of the second columnar section.

2. An optical element according to claim 1, wherein the first insulation layer covers the entire outer circumference of the upper surface of the first columnar section.

3. An optical element according to claim 1, comprising a first electrode that joins with an upper surface of the first columnar section and electrically connects to the surface-emitting type semiconductor laser formed on the first insulation layer, wherein at least a portion of the first insulation layer below the first electrode covers the upper surface of the first columnar section.

4. An optical element according to claim 1, wherein the first insulation layer covers the upper surface of the first columnar section from an outer circumferential end section thereof toward a center thereof by at least 1 μm.

5. An optical element according to claim 1, wherein the second insulation layer covers the entire outer circumference of the upper surface of the second columnar section.

6. An optical element according to claim 1, comprising a second electrode that joins with the upper surface of the second columnar section and electrically connects to the light-receiving element formed on the second insulation layer, wherein at least a portion of the second insulation layer below the second electrode covers the upper surface of the second columnar section.

7. An optical element according to claim 1, wherein the second insulation layer is formed on the upper surface of the first columnar section continuously with the first insulation layer from an edge section of the first insulation layer.

8. An optical element according to claim 1, wherein the first insulation layer covers a portion of the second insulation layer, a second electrode that joins with the upper surface of the second columnar section and electrically connects to the light-receiving element is formed on the first insulation layer.

9. An optical element according to claim 1, wherein the second insulation layer covers the upper surface of the second columnar section from an outer circumferential end section thereof toward a center thereof by at least 1 μm.

10. A method for manufacturing an optical element equipped with a surface-emitting type semiconductor laser that emits laser light in a direction vertical to a surface of a substrate and a light-receiving element, the method comprising the steps of:
forming, on the substrate, a plurality of semiconductor layers for composing the surface-emitting type semiconductor laser and the light-receiving element;
etching the semiconductor layers to form a first columnar section including at least a part of the surface-emitting type semiconductor laser;
etching the semiconductor layers to form a second columnar section including at least a part of the light-receiving element;
forming a first insulation layer that covers a side surface and a part of an upper surface of the first columnar section; and
forming a second insulation layer that covers a side surface and a part of an upper surface of the second columnar section.

11. A method for manufacturing an optical element according to claim 10, wherein the step of forming the first insulation layer includes the steps of forming a precursor layer that covers the side surface and the upper surface of the first columnar section, patterning the precursor layer formed on the upper surface of the first columnar section such that the precursor layer covers at least a portion of the upper surface of the first columnar section, and hardening the precursor layer.

12. A method for manufacturing an optical element according to claim 11, wherein the precursor layer is patterned by using one of a dry etching method and a wet etching method.

13. A method for manufacturing an optical element according to claim 11, wherein the precursor layer is patterned such that the precursor layer covers the upper surface of the first columnar section from an outer circumferential end section thereof toward a center thereof by at least 1 μm.

14. A method for manufacturing an optical element according to claim 10, wherein the step of forming the second insulation layer includes the steps of forming an insulation layer that covers a side surface and an upper surface of the second columnar section, and patterning the insulation layer formed on the upper surface of the second columnar section such that the insulation layer covers a portion of the upper surface of the second columnar section.

15. A method for manufacturing an optical element according to claim 14, wherein the insulation layer is formed by a plasma CVD method.

16. A method for manufacturing an optical element according to claim 14, wherein the insulation layer is patterned by using one of a dry etching method and a wet etching method.

17. A method for manufacturing an optical element according to claim 14, wherein the insulation layer is patterned such that the insulation layer covers the upper surface of the second columnar section from an outer circumferential end section thereof toward a center thereof by at least 1 μm.
